(19) United States
(12) Patent Application Publication
(10) Pub. No.: US 2024/0399700 A1
(43) Pub. Date: Dec. 5, 2024

(54) DISPLAY PANEL ASSEMBLY INCLUDING A FILM LAYER

(71) Applicant: SAMSUNG DISPLAY CO., LTD., Yongin-si (KR)

(72) Inventors: YOUNGMYUNG LEE, Yongin-si (KR); JONG-NAM LEE, Yongin-si (KR); JINHYUK PARK, Yongin-si (KR)

(21) Appl. No.: 18/396,286

(22) Filed: Dec. 26, 2023

(30) Foreign Application Priority Data
May 30, 2023 (KR) 10-2023-0069217

(51) Int. Cl. B32B 3/26; B32B 3/02

(52) U.S. Cl. CPC B32B 3/263; B32B 3/02; B32B 2307/7376; B32B 2457/20

(57) ABSTRACT

A display panel assembly includes a display panel including a light emitting structure and having a rectangular planar shape with rounded corners. A film layer is disposed under the display panel so as to overlap the display panel. The film layer includes a central area having a rectangular planar shape and a peripheral area surrounding the central area. In the peripheral area, the film layer has a thickness change section in which a thickness of the film layer gradually decreases and then gradually increases in a direction away from the central area.

This application claims priority under 35 U.S.C. § 119 to Korean Patent Application No. 10-2023-0069217, filed on May 30, 2023, the content of which are herein incorporated by reference in their entirety.

### TECHNICAL FIELD

The disclosure relates to a display device and, more specifically, to a display panel assembly including a film layer.

### DISCUSSION OF THE RELATED ART

A display device is a device that displays an image and may include a protective window disposed over a display panel assembly. The display panel assembly may include a plurality of pixels. The display device may be formed by attaching the display panel assembly to the window.

Recently, a display device including a window with a curved surface has been in a spotlight. In this case, when attaching the display panel assembly to the window having the curved surface, an attachment defect may occur in the display panel assembly in an area that overlaps the curved surface of the window. Accordingly, display defects in the display device may occur.

### SUMMARY

A display panel assembly includes a display panel including a light emitting structure having a rectangular planar shape with rounded corners and a film layer disposed under the display panel so as to overlap the display panel, and the film layer includes a central area having a rectangular planar shape and a peripheral area surrounding the central area.

In the peripheral area, the film layer has a thickness change section in which a thickness of the film layer gradually decreases and then gradually increases in a direction away from the central area.

A thickness at an edge of the film layer in the peripheral area may be greater than a thickness of the film layer in the central area.

The peripheral area may include an edge area including an edge adjacent area adjacent to one side of the central area and an edge outer area adjacent to the edge area and spaced apart from the central area. A corner adjacent area may be in contact with a corner portion of the central area and the edge adjacent area. A corner outer area may be in contact with the corner adjacent area and the edge outer area.

A thickness of the film layer in the edge outer area may gradually decrease and then gradually increase in a direction away from the edge adjacent area.

With respect to a first extension direction having a same relative angle with respect to an extension direction of a first side in contact with the corner portion of the central area and an extension direction of a second side in contact with the corner portion of the central area, a thickness of the film layer in the corner adjacent area may gradually decrease away from the central area along the first extension direction.

A thickness of the film layer in the corner outer area may gradually increase away from the central area along the first extension direction.

The film layer may include an upper surface and a lower surface, and the upper surface of the film layer may be flat.

The display panel may be disposed on the upper surface of the film layer.

A thickness of the film layer may be constant in the central area.

The display panel assembly may further include a functional layer disposed on the display panel.

The functional layer may include a polarizing layer, a touch sensing layer, and/or a color conversion layer.

The display panel assembly may further include an adhesive layer disposed on the functional layer.

A display device includes a display panel including a light emitting structure and having a rectangular planar shape with rounded corners and a film layer disposed under the display panel so as to overlap the display panel. The film layer includes a central area having a rectangular planar shape, a first peripheral area surrounding the central area, a second peripheral area surrounding the first peripheral area, and a third peripheral area surrounding the second peripheral area.

A thickness of the film layer in the second peripheral area may be smaller than each of a thickness of the film layer in the first peripheral area and a thickness of the film layer in the third peripheral area.

The thickness of the film layer in the first peripheral area may be constant. The thickness of the film layer in the second peripheral area may be constant. The thickness of the film layer in the third peripheral area may be constant.

The thickness of the film layer in the first peripheral area may be equal to the thickness of the film layer in the third peripheral area.

The thickness of the film layer in the first peripheral area may be equal to the thickness of the film layer in the central area.

The film layer may include a first film layer and a second film layer disposed on one side of the first film layer.

The display panel assembly may further include a functional layer disposed on the display panel.

The functional layer may include a polarizing layer, a touch sensing layer, and/or a color conversion layer.

The display panel assembly may further include an adhesive layer disposed on the functional layer.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a cross-sectional view illustrating a display panel assembly according to an embodiment.

FIG. 2 is a plan view illustrating a display panel included in a display panel assembly of FIG. 1.

FIG. 3 is a plan view illustrating a film layer included in a display panel assembly of FIG. 1.

FIG. 4 is an enlarged plan view of area AA of FIG. 3.

FIG. 5 is a diagram illustrating a film layer of FIG. 4.

FIG. 6 is a plan view illustrating a film layer according to an embodiment.

FIG. 7 is an enlarged plan view of an area BB in FIG. 6.

FIGS. 8A to 8C are cross-sectional views illustrating a film layer according to a first embodiment.

FIGS. 9A to 9C are cross-sectional views illustrating a film layer according to an embodiment.

FIGS. 10A to 10C are cross-sectional views illustrating a film layer according to an embodiment.

FIGS. 11 and 12 are views illustrating a method of manufacturing a display device including a display panel assembly of FIG. 1.

FIG. 13 is a plan view illustrating a window in FIGS. 11 and 12.

FIG. 14 is a cross-sectional view taken along line I-I′ of FIG. 13.

FIG. 15 is a cross-sectional view taken along line II-II′ of FIG. 13.

### DETAILED DESCRIPTION

The invention now will be described more fully hereinafter with reference to the accompanying drawings, in which various embodiments are shown. This invention may, however, be embodied in many different forms, and should not necessarily be construed as limited to the embodiments set forth herein. Rather, these embodiments are provided so that this disclosure will be thorough and complete, and will fully convey the scope of the invention to those skilled in the art. Like reference numerals may refer to like elements throughout the specification and the disclosure.

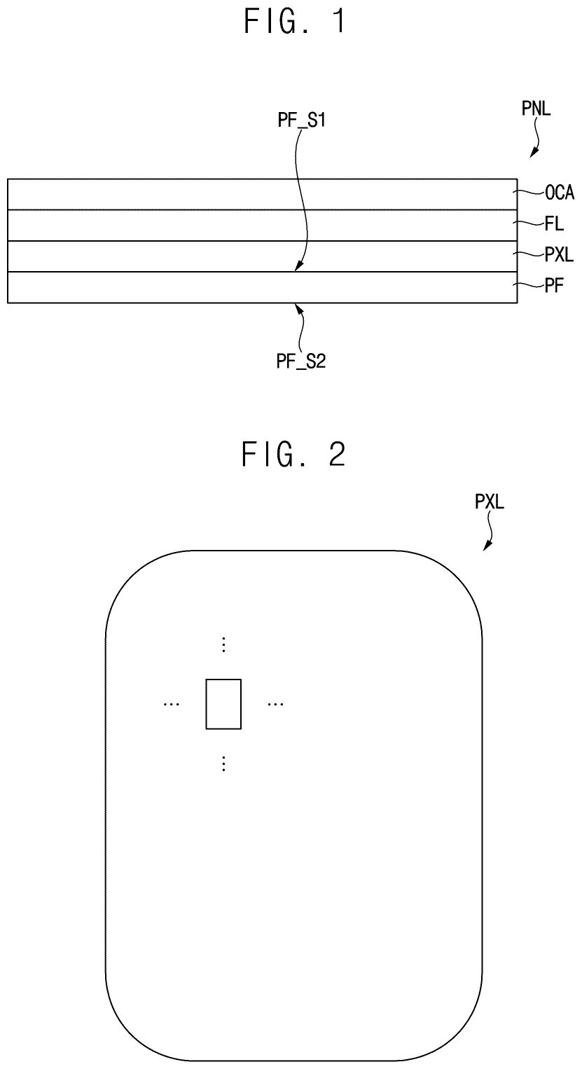

FIG. 1 is a view illustrating a display panel assembly according to an embodiment.

Referring to FIG. 1, a display panel assembly PNL may include a film layer PF, a display panel PXL, a functional layer FL, and an optically clear adhesive layer OCA.

The display panel PXL may include at least a light emitting structure. The light emitting structure may include a pixel (PX in FIG. 2), and a pixel driver that provides a driving signal to the pixel, or the like. Accordingly, an image may be displayed on the display panel PXL.

The film layer PF may be disposed under the display panel PXL. Accordingly, the film layer PF may serve to protect a lower surface of the display panel PXL.

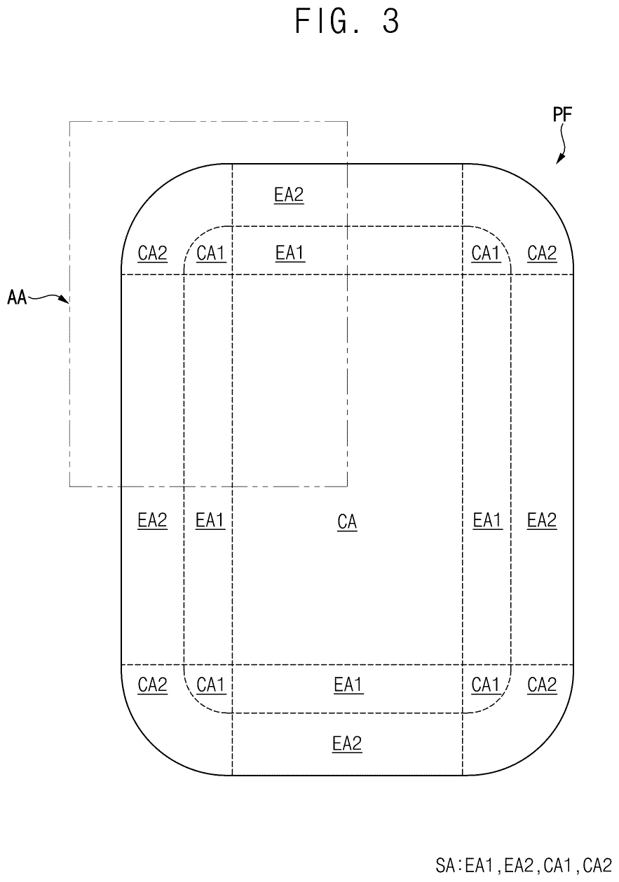

The film layer PF may include an upper surface PF_S1 and a lower surface PF_S2 opposite the upper surface PF_S1. The upper surface PF_S1 of the film layer PF may be substantially flat (i.e., planar). In contrast, the lower surface PF_S2 of the film layer PF might not be substantially flat. This will be described later with reference to FIGS. 3 to 5.

The functional layer FL may be disposed on the display panel PXL. The functional layer FL may include a polarizing layer, a touch sensing layer, and/or a color conversion layer.

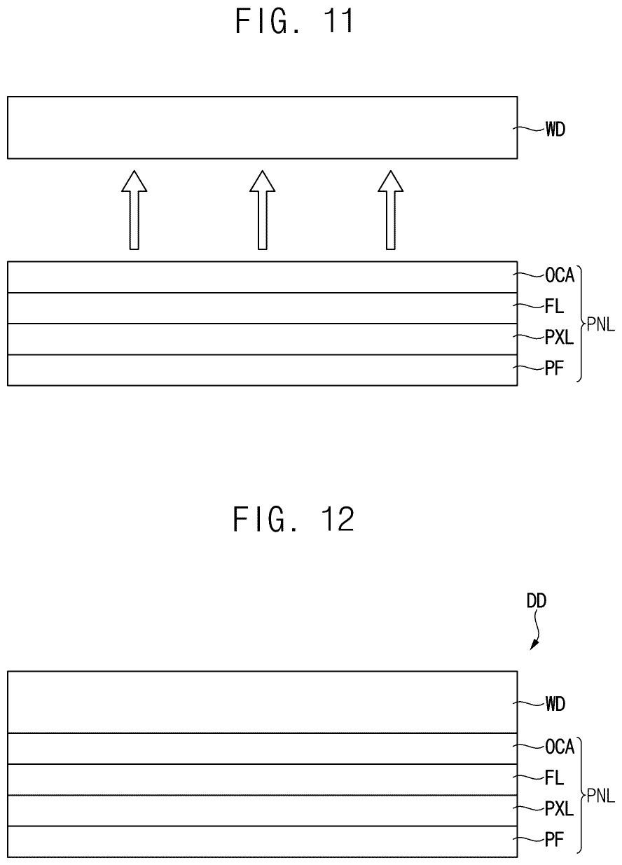

The adhesive layer OCA may be disposed on the functional layer FL. The adhesive layer OCA may include various known materials having adhesive properties. By the adhesive layer OCA, the display panel assembly PNL may be attached under a window (WD in FIG. 11) to be described later, and thus a display device (DD in FIG. 12) may be manufactured.

FIG. 2 is a plan view illustrating a display panel included in a display panel assembly of FIG. 1.

Referring to FIG. 2, the display panel PXL may have a rectangular planar shape with rounded corners. In this case, the pixels PX may be disposed entirely on the display panel PXL. The pixels PX may emit light, and the display panel PXL may display an image by combining light emitted from the pixels PX.

FIG. 3 is a plan view illustrating a film layer included in a display panel assembly of FIG. 1.

The film layer PF may have a planar shape that is substantially the same as a planar shape of the display panel PXL. For example, the film layer PF may have a rectangular planar shape with rounded corners. Additionally, the film layer PF may completely overlap the display panel PXL. For example, the upper surface PF_S1 of the film layer PF may be attached to the lower surface of the display panel PXL and may cover the lower surface of the display panel PXL entirely.

The film layer PF may be divided into a central area CA and a peripheral area SA surrounding the central area CA.

The central area CA may have a rectangular planar shape. In this case, an edge of the peripheral area SA surrounding the central area CA may have a rectangular planar shape with rounded corners.

The peripheral area SA may include an edge adjacent area EA1 adjacent to one side of the central area CA and an edge outer area EA2 adjacent to the edge adjacent area EA1 and spaced apart from the central area CA. The edge adjacent area EA1 and the edge outer area EA2 may be referred to as an edge area. Each of the edge adjacent area EA1 and the edge outer area EA2 may have a substantially rectangular planar shape.

In addition, the surrounding area SA may include a corner adjacent area CA1 that is in contact with a corner portion of the central area CA and the edge adjacent area EA1, and a corner outer area CA2 that is in contact with the corner adjacent area CAL and the edge outer area EA2. The corner adjacent area CAL and the corner outer area CA2 may be referred to as a corner area. The corner area may have a substantially fan-shaped planar shape.

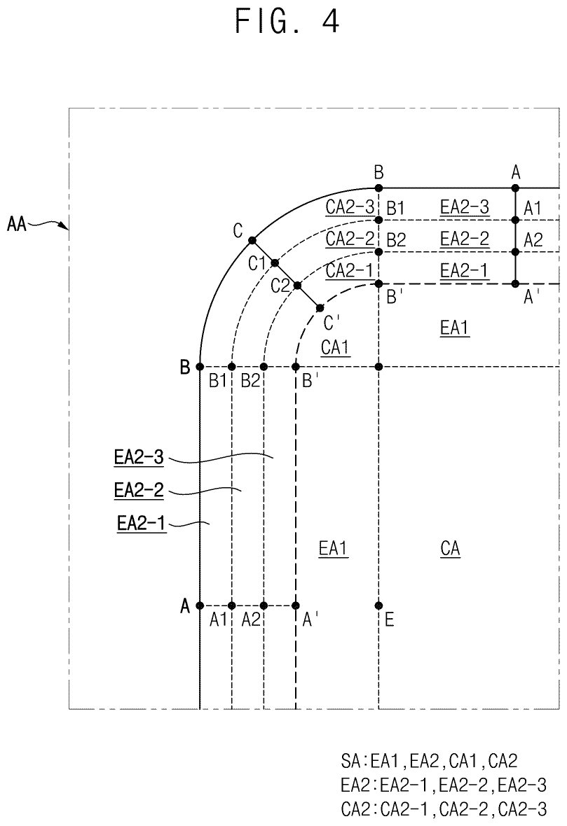

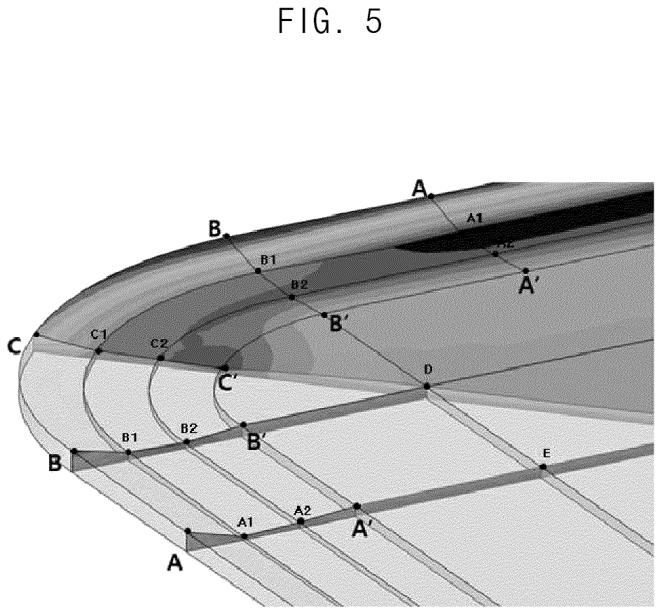

FIG. 4 is an enlarged plan view of area AA of FIG. 3. FIG. 5 is a diagram illustrating a film layer of FIG. 4.

Referring to FIGS. 4 and 5, in the peripheral area SA, the film layer PF may have a thickness change section in which a thickness of the film layer gradually decreases and then gradually increases in a direction away from the central area CA. As used herein, the term “gradually” is intended to mean that the transition of thickness occurs on a continuous basis rather than abruptly and is not used as a subjective description of a degree to which the transition occurs.

In an embodiment, a thickness of the film layer PF in the edge outer area EA2 may gradually decrease and then gradually increase in a direction away from the edge adjacent area EA1.

For example, at a boundary between the edge outer area EA2 and the edge adjacent area EA1, distribution thickness of the film layer PF from a point A′ spaced apart from the corner outer area CA2 to a point A located on the outermost edge of the film layer PF closest to the point A′ may gradually decrease and then gradually increase in a direction away from the edge adjacent area EA1.

In addition, at the boundary between the edge outer area EA2 and the edge adjacent area EA1, distribution thickness of the film layer PF from a point B′ spaced apart from the corner outer area CA2 to a point B located on the outermost edge of the film layer PF closest to the point B′ may gradually decrease and then gradually increase in a direction away from the edge adjacent area EA1.

For example, if the edge outer area EA2 is divided into thirds in a direction away from the edge adjacent area EA1, into a first edge outer area EA2-1, a second edge outer area EA2-2, and a third edge outer area EA2-3 for convenience of explanation, a point A2 where a line segment connecting the point A and the point A′ and the boundary between the first edge outer area EA2-1 and the second edge outer area EA2-2 meets and a point A1 where the line segment connecting the point A and the point A′ and the boundary between the second edge outer area EA2-2 and the third edge outer area EA2-3 meets may be defined. The point A1 and the point A2 may divide the line segment A-A′ into thirds.

In this case, in an embodiment, a thickness of the film layer PF at the point A′ may be about 99 micrometers, a thickness of the film layer PF at the point A2 may be about 54 micrometers, a thickness of the film layer PF at the point A1 may be about 34 micrometers, and a thickness of the film layer PF at the point A may be about 182 micrometers. In addition, a thickness of the film layer PF may gradually decrease from the point A′ to the point A2, a thickness of the film layer PF may gradually decrease from the point A2 to the point A1, and a thickness of the film layer PF may gradually increase from the point A1 to the point A.

In addition, a point B2 where a line segment connecting the point B and the point B′ and the boundary between the first edge outer area EA2-1 and the second edge outer area EA2-2 meets and a point B1 where the line segment connecting the point B and the point B′ and the boundary between the second edge outer area EA2-2 and the third edge outer area EA2-3 meets may be defined. The point B1 and the point B2 may divide the line segment B-B′ into thirds.

In this case, in an embodiment, a thickness of the film layer PF at the point B′ may be about 102 micrometers, a thickness of the film layer PF at the point B2 may be about 54 micrometers, a thickness of the film layer PF at the point B1 may be about 75 micrometers, and a thickness of the film layer PF at the point B may be about 198 micrometers. In addition, a thickness of the film layer PF may gradually decrease from the point B′ to the point B2, a thickness of the film layer PF may gradually decrease from the point B2 to the point B1, and a thickness of the film layer PF may gradually increase from the point B1 to the point B.

In an embodiment, a line segment C-C′ extending in a first extension direction having a same relative angle with respect to an extension direction of the first side in contact with a corner portion D of the central area CA and an extension direction of the second side in contact with the corner portion D of the central area CA. In this case, a point C′ of the line segment C-C′ may be located on a boundary between the corner adjacent area CAL and the corner outer area CA2, and a point C may be located on the outermost edge of the film layer PF closest to the point C′. Additionally, the corner portion D of the central area CA may be located on an extension line of the line segment C-C′.

In this case, a thickness of the film layer PF in the corner adjacent area CA1 may gradually decrease as far away from the central area CA along the first extension direction toward the point C′.

For example, in an embodiment, a thickness of the film layer PF at the corner portion D of the central area CA may be about 100 micrometers, and a thickness of the film layer PF at the point C′ may be about 46 micrometers. Additionally, a thickness of the film layer PF may gradually decrease from the corner portion D of the central area CA to the point C″.

Additionally, a thickness of the film layer PF in the corner outer area CA2 may gradually increase in the first extending direction from the point C′ to the point C.

For example, if the corner outer area CA2 is divided into thirds in a direction away from the corner adjacent area CA1, into a first corner outer area CA2-1, a second corner outer area CA2-2, and a third corner outer area CA2-3 for convenience of explanation, a point C2 where the line segment connecting the point C and the point C′ and the boundary between the first corner outer area CA2-1 and the second corner outer area CA2-2 meets and a point C1 where the line segment connecting the point C and the point C′ and the boundary between the second edge outer area EA2-2 and the third edge outer area EA2-3 meets may be defined. The point C1 and the point C2 may divide the line segment C-C′ into thirds.

In this case, in an embodiment, a thickness of the film layer PF at the point C′ may be about 46 micrometers, a thickness of the film layer PF at the point C2 may be about 64 micrometers, a thickness of the film layer PF at the point C1 may be about 75 micrometers, and a thickness of the film layer PF at the point C may be about 156 micrometers. In addition, a thickness of the film layer PF may gradually increase from the point C′ to the point C2, a thickness of the film layer PF may gradually increase from the point C2 to the point C1, and a thickness of the film layer PF may gradually increase from the point C1 to the point C.

In an embodiment, as described above with reference to FIG. 1, the upper surface PF_S1 of the film layer PF may be substantially flat. In this case, as explained with reference to FIGS. 4 and 5, a thickness of the film layer PF may vary depending on an area (or point), and the lower surface PF_S2 of the film layer PF might not be substantially flat.

In an embodiment, a thickness of the film layer PF in the central area CA may be substantially constant. For example, a thickness of the film layer PF in the central area CA may be about 100 micrometers. For example, a thickness of the film layer PF at a point E located at a boundary between the central area CA and the edge adjacent area EA1 may be about 100 micrometers.

In this case, a thickness of the film layer PF in the central area CA may be smaller than a thickness of the film layer PF at edges in the peripheral area SA. For example, a thickness of the film layer PF at the central area CA may be about 100 micrometers, a thickness of the film layer PF at the point A may be about 182 micrometers, and a thickness of the film layer PF at the point B may be about 198 micrometers, a thickness of the film layer PF at the point B may be about 198 micrometers, and a thickness of the film layer PF at the point C may be about 156 micrometers.

In an embodiment, a thickness of the film layer PF may gradually change or may be substantially constant between two different points located in the peripheral area SA of the film layer PF. For example, a thickness of the film layer PF may gradually decrease from the point C2 to the point B2 along the boundary between the first corner outer area CA2-1 and the second corner outer area CA2-2. For example, a thickness of the film layer PF may be constant from the point C1 to the point B1 along the boundary between the second corner outer area CA2-2 and the third corner outer area CA2-3. For example, a thickness of the film layer PF may be substantially constant along a straight path from the point B2 to the point A2. For example, a thickness of the film layer PF may gradually decrease along a straight path from the point B1 to the point A1.

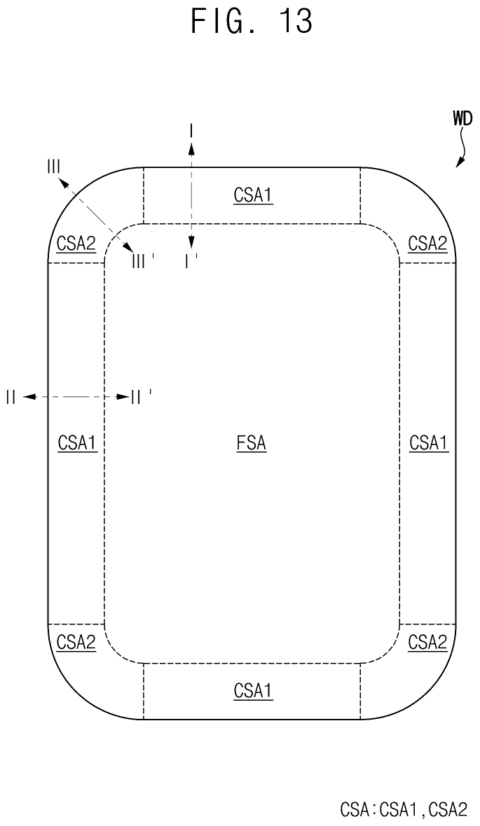

As explained with reference to FIGS. 3 to 5, in the peripheral area SA, the film layer PF may have the thickness change section in which a thickness of the film layer PF gradually decreases and then gradually increases in a direction away from the central area CA. Accordingly, when attaching the display panel assembly PNL including the film layer PF to the window (WD in FIG. 13) including a curved surface described later, attaching defect of the display panel assembly PNL might not occur in an area overlapping the curved surface of the window WD. This will be described in detail later with reference to FIG. 17.

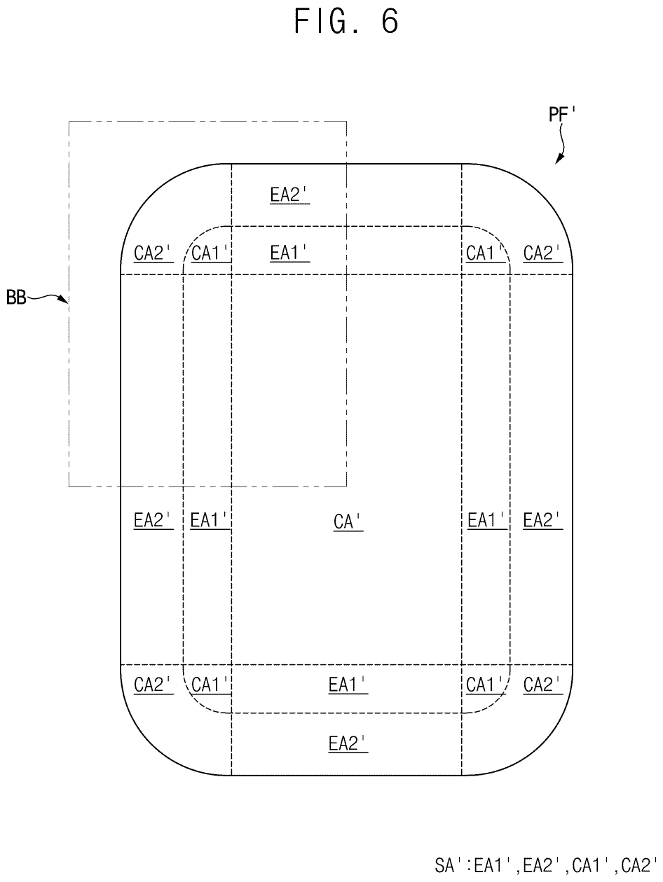

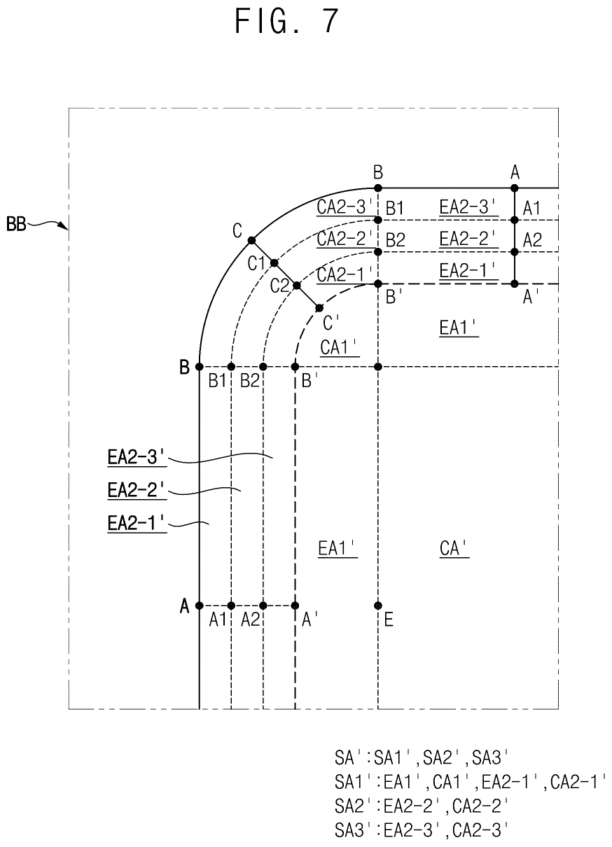

FIG. 6 is a plan view illustrating a film layer according to an embodiment. FIG. 7 is an enlarged plan view of an area BB in FIG. 6.

Referring to FIG. 6, a film layer PF may be substantially similar to the film layer PF described with reference to FIGS. 3 to 5. Therefore, the film layer PF′ will be described based on differences from the film layer PF and to the extent that elements are not described, it is to be understood that these elements are at least similar to corresponding elements that have been described elsewhere within the present disclosure.

The film layer PF′ may be divided into a central area CA′ and a peripheral area SA′ surrounding the central area CA′. Additionally, the surrounding area SA′ may include an edge adjacent area EA1′, an edge outer area EA2′, a corner adjacent area CA1′, and a corner outer area CA2′.

In this case, the central area CA′, the peripheral area SA′, and the edge adjacent area EA1′, the edge outer area EA2′, the corner adjacent area CA1′, and the corner outer area CA2′ included in the peripheral area SA′ may be substantially the same as the central area CA, the peripheral area SA, and the edge adjacent area EA1, the edge outer area EA2, the corner adjacent area CA1, and the corner outer area CA2 included in the peripheral area SA described with reference to FIG. 3.

Referring to FIG. 7, the edge outer area EA2′ may be divided into a first edge outer area EA2-1′, a second edge outer area EA2-2′, and a third edge outer area EA2-3′, and the corner outer area CA2′ may be divided into a first corner outer area CA2-1′, a second corner outer area CA2-2′, and a third corner outer area CA2-3″.

In this case, the first edge outer area EA2-1′, the second edge outer area EA2-2′, the third edge outer area EA2-3′, the first corner outer area CA2-1′, the second corner outer area CA2-2′, and the third corner outer area CA2-3′ may be substantially the same as the first edge outer area EA2-1, the second edge outer area EA2-2, the third edge outer area EA2-3, the first corner outer area CA2-1, the second corner outer area CA2-2, and the third corner outer area CA2-3 described with reference to FIG. 4.

In the film layer PF′, the peripheral area SA′ may be divided into a first peripheral area SA1′, a second peripheral area SA2′, and a third peripheral area SA3″.

The first peripheral area SA1′ may surround the central area CA′. The first peripheral area SA1′ may include the edge adjacent area EA1′, the first edge outer area EA2-1′, the corner adjacent area CA1′, and the first corner outer area CA2-1.

The second peripheral area SA2′ may surround the first peripheral area SA1′. The second peripheral area SA2′ may include the second edge outer area EA2-2′, the second corner outer area CA2-2′.

The third peripheral area SA3′ may surround the second peripheral area SA2″. The third peripheral area SA3′ may include the third edge outer area EA2-3′, the third corner outer area CA2-3′.

In an embodiment, a thickness of the film layer PF′ in the second peripheral area SA2′ may be smaller than a thickness of the film layer PF′ in the first peripheral area SA1″. Additionally, a thickness of the film layer PF′ in the second peripheral area SA2′ may be smaller than a thickness of the film layer PF′ in the third peripheral area SA3′.

In this case, each of a thickness of the film layer PF′ in the first peripheral area SA1′, a thickness of the film layer PF′ in a second peripheral area SA2′, and a thickness of the film layer PF′ in a third peripheral area SA3′ may be relatively constant.

In an embodiment, a thickness of the film layer PF′ in the first peripheral area SA1′ may be substantially the same as a thickness of the film layer PF′ in the third peripheral area SA3′. In this case, a thickness of the film layer PF′ in the first peripheral area SA1′ may be substantially the same as a thickness of the film layer PF′ in the central area CA′.

For example, the film layer PF′ may have a first thickness throughout the first peripheral area SA1′, the third peripheral area SA3′, and the central area CA′, and have a second thickness that is smaller than the first thickness in the second peripheral area SA2′. For example, the film layer PF′ may include a groove having a depth in a direction from a lower surface of the film layer PF′ toward an upper surface of the film layer PF′ in the second peripheral area SA2′.

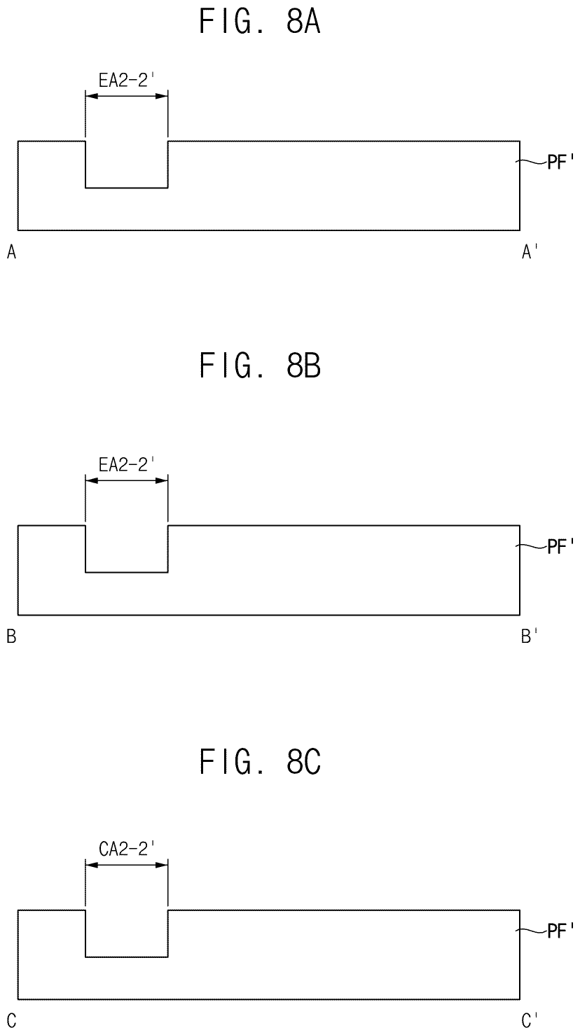

FIGS. 8A to 8C are cross-sectional views illustrating a film layer according to an embodiment.

Referring to FIGS. 7 and 8A to 8C, the film layer PF′ may have a single-layer structure. In addition, the film layer PF′ may include a groove having a depth in a direction from a lower surface of the film layer PF′ toward an upper surface of the film layer PF′ in the second peripheral area SA2′. Accordingly, a thickness of the film layer PF′ in the second peripheral area SA2′ may be relatively small.

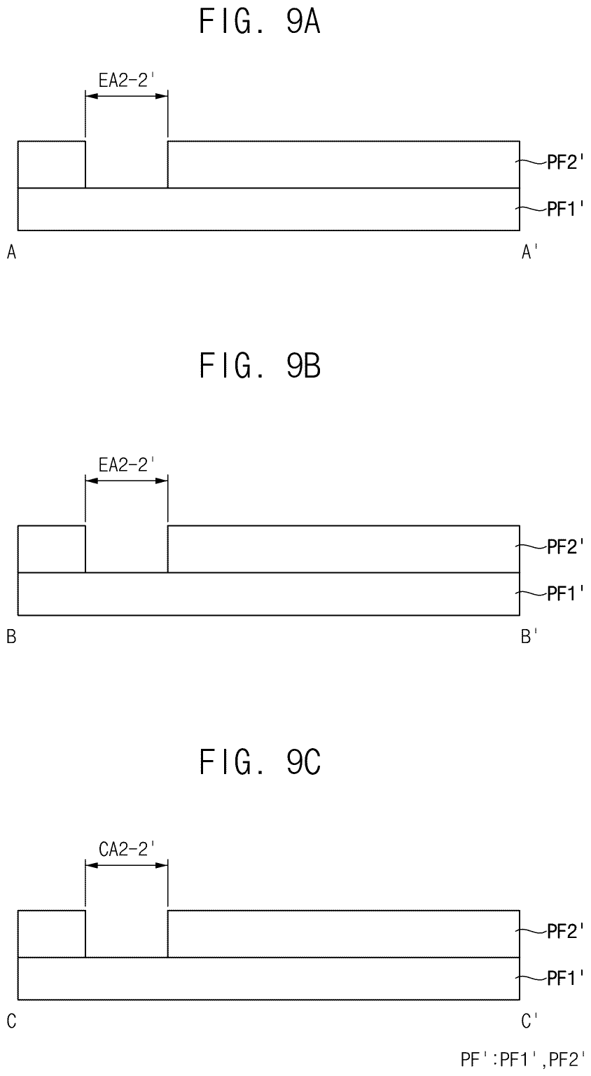

FIGS. 9A to 9C are cross-sectional views illustrating a film layer according to an embodiment.

Referring to FIGS. 7 and 9A to 9C, the film layer PF′ may have a multilayer structure of a first film layer PF1′ and a second film layer PF2′. In this case, the second film layer PF2′ may be removed from the second peripheral area SA2′, and accordingly, a thickness of the film layer PF′ in the second peripheral area SA2′ may be relatively small.

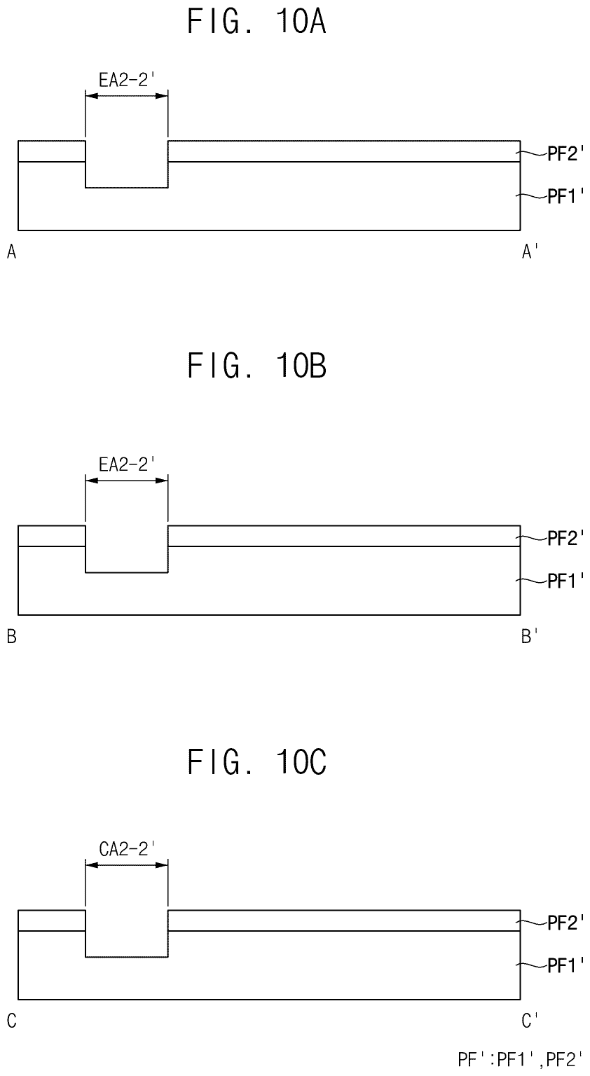

FIGS. 10A to 10C are cross-sectional views illustrating a film layer according to an embodiment.

Referring to FIGS. 7 and 10A to 10C, the film layer PF′ may have a multilayer structure of a first film layer PF1′ and a second film layer PF2′. In this case, the second film layer PF2′ may be removed from the second peripheral area SA2′, and the first film layer PF1′ may include a groove. Accordingly, a thickness of the film layer PF′ in the second peripheral area SA2′ may be relatively small.

As described with reference to FIGS. 6 to 10C, a thickness of the film layer PF′ in the second peripheral area SA2′ may be relatively small. Accordingly, when attaching the display panel assembly PNL including the film layer PF′ to the window WD including a curved surface, attaching defect of the display panel assembly PNL might not occur in an area overlapping the curved surface of the window WD.

FIGS. 11 and 12 are views illustrating a method of manufacturing a display device including a display panel assembly of FIG. 1.

Referring to FIG. 11, the display panel assembly PNL and the window WD may be manufactured separately. In this case, the display panel assembly PNL may be attached to the lower surface of the window WD. For example, the display panel assembly PNL may be pressed in a direction toward the lower surface of the window WD.

Referring to FIG. 12, the display device DD may be manufactured by attaching the display panel assembly PNL under the window WD.

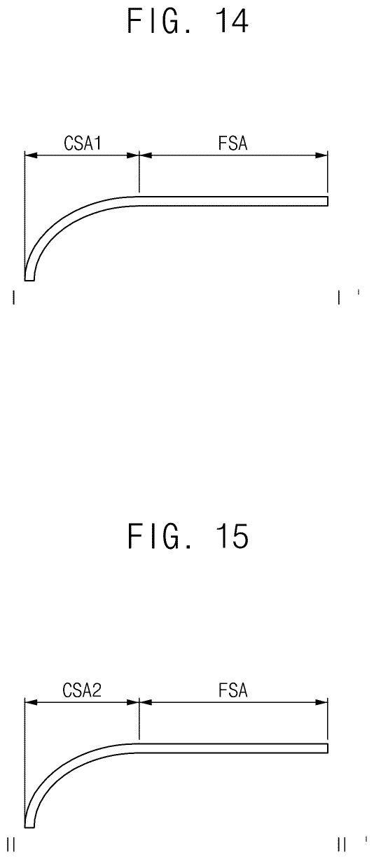

FIG. 13 is a plan view illustrating a window in FIGS. 11 and 12. FIG. 14 is a cross-sectional view taken along line I-I′ of FIG. 13. FIG. 15 is a cross-sectional view taken along line II-II′ of FIG. 13.

Referring to FIGS. 13 to 15, the window WD may include a flat area FSA and a curved area CSA surrounding the flat area FSA.

In the flat area FSA, the window WD may have a substantially flat surface. In this case, in the display device DD, the flat area WD of the window WD may overlap the central area CA, the edge adjacent area EA1, and the corner adjacent area CA1 of the film layer PF described with reference to FIG. 3.

In the curved area CSA, the window WD may have a curved surface. The curved area CSA may include a first curved area CSA1 and a second curved area CSA2.

In this case, in the display device DD, the first curved area CSA1 of the window WD may overlap the edge outer area EA2 of the film layer PF described with reference to FIG. 3, and the window, and the second curved area CSA2 of the window WD may overlap the corner outer area CA2 of the film layer PF described with reference to FIG. 3.

When the display panel assembly PNL including the film layer PF described with reference to FIGS. 2 to 5 is attached to the window WD, attaching defect might not occur in the display panel assembly PNL in an area that overlaps the second curved area CSA2 of the window WD.

In contrast, if a thickness of the film layer included in the display panel assembly is constant, when the display panel assembly is attached to the window WD, attaching defect may occur in the display panel assembly PNL in an area that overlaps the second curved area CSA2 of the window WD.

For example, when evaluating an impact of buckling in an area overlapping with the second curved area CSA2 of the window WD, in a conventional case, the display panel assembly was curled near the edge of the window WD, and buckling occurred. On the other hand, in an embodiment, buckling did not substantially occur in the display panel assembly PNL near the edge of the window WD.

In addition, when evaluating an impact of pressing in an area overlapping with the second curved area CSA2 of the window WD, in a conventional case, pressing occurred on an adhesive layer included in the display panel assembly in an area adjacent to the flat area FSA of the window WD. On the other hand, in an embodiment, the adhesive layer OCA included in the display panel assembly PNL was not be substantially pressed in an area adjacent to the flat area FSA of the window WD.

In addition, when evaluating an impact of strain in an area overlapping with the second curved area CSA2 of the window WD, in a conventional case, the display panel assembly had a relatively large strain value in the curved area CSA. On the other hand, in an embodiment, the display panel assembly PNL had a relatively small strain value in the curved area CSA of the window WD.

The invention should not necessarily be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention.

What is claimed is:

1. A display panel assembly, comprising:
a display panel including a light emitting structure having a rectangular planar shape with rounded corners; and
a film layer disposed under the display panel and overlapping the display panel, the film layer including a central area having a rectangular planar shape and a peripheral area surrounding the central area,
wherein in the peripheral area, the film layer has a thickness change section in which a thickness of the film layer gradually decreases and then gradually increases in a direction away from the central area.

2. The display panel assembly of claim 1, wherein a thickness of the film layer at an edge of the film layer in the peripheral area is greater than a thickness of the film layer in the central area.

3. The display panel assembly of claim 1, wherein the peripheral area includes an edge area including an edge adjacent area adjacent to one side of the central area and an edge outer area adjacent to the edge area and spaced apart from the central area, a corner adjacent area in contact with a corner portion of the central area and the edge adjacent area, and a corner outer area in contact with the corner adjacent area and the edge outer area.

4. The display panel assembly of claim 3, wherein a thickness of the film layer in the edge outer area gradually decreases and then gradually increases in a direction away from the edge adjacent area.

5. The display panel assembly of claim 2, wherein with respect to a first extension direction having a same relative angle with respect to an extension direction of a first side in contact with the corner portion of the central area and an extension direction of a second side in contact with the corner portion of the central area, a thickness of the film layer in the corner adjacent area gradually decreases away from the central area along the first extension direction.

6. The display panel assembly of claim 5, wherein a thickness of the film layer in the corner outer area gradually increases away from the central area along the first extension direction.

7. The display panel assembly of claim 1, wherein the film layer includes an upper surface and a lower surface, and
wherein the upper surface of the film layer is flat.

8. The display panel assembly of claim 7, wherein the display panel is disposed on the upper surface of the film layer.

9. The display panel assembly of claim 1, wherein a thickness of the film layer is constant in the central area.

10. The display panel assembly of claim 1, further comprising:
a functional layer disposed on the display panel.

11. The display panel assembly of claim 10, wherein the functional layer includes at a polarizing layer, a touch sensing layer, and/or a color conversion layer.

12. The display panel assembly of claim 10, further comprising:
an adhesive layer disposed on the functional layer.

13. A display panel assembly, comprising:
a display panel including a light emitting structure, the display panel having a rectangular planar shape with rounded corners; and
a film layer disposed under the display panel and overlapping the display panel, the film layer including a central area having a rectangular planar shape, a first peripheral area surrounding the central area, a second peripheral area surrounding the first peripheral area, and a third peripheral area surrounding the second peripheral area,
wherein a thickness of the film layer in the second peripheral area is smaller than each of a thickness of the film layer in the first peripheral area and a thickness of the film layer in the third peripheral area.

14. The display panel assembly of claim 13, wherein the thickness of the film layer in the first peripheral area is constant,
wherein the thickness of the film layer in the second peripheral area is constant, and
wherein the thickness of the film layer in the third peripheral area is constant.

15. The display panel assembly of claim 13, wherein the thickness of the film layer in the first peripheral area is equal to the thickness of the film layer in the third peripheral area.

16. The display panel assembly of claim 15, wherein the thickness of the film layer in the first peripheral area is equal to the thickness of the film layer in the central area.

17. The display panel assembly of claim 13, wherein the film layer includes:
a first film layer; and
a second film layer disposed on one side of the first film layer.

18. The display panel assembly of claim 13, further comprising:
a functional layer disposed on the display panel.

19. The display panel assembly of claim 18, wherein the functional layer includes a polarizing layer, a touch sensing layer, and/or a color conversion layer.

20. The display panel assembly of claim 18, further comprising:
an adhesive layer disposed on the functional layer.
